(19) United States
(12) Patent Application Publication
(10) Pub. No.: US 2016/0290781 A1
(43) Pub. Date: Oct. 6, 2016

(54) APPARATUS AND METHODS FOR DETECTING SUBSTRATE ALIGNMENT DURING A PRINTING PROCESS

(71) Applicant: EMPIRE TECHNOLOGY DEVELOPMENT LLC, Wilmington, DE (US)

(72) Inventors: Feng WAN, Issaquah, WA (US); Yiyang WANG, Seattle, WA (US); Kenichi HASHIZUME, Kitagunma, Gunma, (JP); Shunichiro KUROKI, Tokyo (JP)

(73) Assignee: EMPIRE TECHNOLOGY DEVELOPMENT LLC, Wilmington, DE (US)

(21) Appl. No.: 15/035,472

(22) PCT Filed: Nov. 8, 2013
(86) PCT No.: PCT/US13/69234

§ 371 Date: May 9, 2016

(51) Int. Cl. G01B 7/30; G01B 7/16; H05K 1/02; H05K 3/12; H05K 1/16

(52) U.S. Cl. CPC G01B 7/30; H05K 3/125; H05K 1/16; H05K 1/0296; G01B 7/16; H05K 2203/166; H05K 2203/163; H05K 2201/10151; H05K 2203/1545

(57) ABSTRACT

Printing apparatuses for detection of substrate alignment, methods for manufacture and use thereof, and substrates are disclosed. One printing apparatus may include a printing assembly having at least one conductive alignment sensor with a plurality of inductive coils configured to generate an electromagnetic field. The printing assembly may receive at least one substrate having at least one conductive portion and align the substrate such that the plurality of inductive coils and the conductive portion substantially overlap with each other to form an electromagnetic field having a direction from the at least one conductive alignment sensor to the at least one conductive portion. The direction of the electromagnetic field with respect to the conductive alignment sensor may form an angle. The conductive alignment sensor may be configured to detect a movement of the conductive portion when a change to the angle causes a current change through the plurality of inductive coils.

### BACKGROUND

Printable electronics manufacturing technologies have been increasingly used in the electronics manufacturing industry because their use allows for time savings, money savings, and a reduction in environmental impact. In particular, the technologies use an additive process for constructing electronics components rather than a subtractive process that accumulates waste from portions that are not used in the end products. One particular printable electronics manufacturing technology that has been used more frequently is a reel-to-reel printing process due to its potential for low cost production and the high speed at which it operates.

Increasing productivity and yield of reel-to-reel printing processes is of common interest. Productivity can be improved by using a wide-width substrate and printing at high speeds. However, using a wide-width substrate and increasing the printing speeds can cause errors to occur more frequently, such as a misalignment of the substrate on one or more of the reels.

### SUMMARY

In an embodiment, a printing apparatus may include a printing assembly having at least one conductive alignment sensor with a plurality of inductive coils configured to generate an electromagnetic field. The printing assembly may be configured to receive at least one substrate having at least one conductive portion and align the substrate such that the plurality of inductive coils and the conductive portion substantially overlap with each other to form an electromagnetic field having a direction from the at least one conductive alignment sensor to the at least one conductive portion. The direction of the electromagnetic field with respect to the conductive alignment sensor may form an angle. The conductive alignment sensor may be configured to detect a movement of the conductive portion when a change to the angle causes a change in a current through the plurality of inductive coils.

In an embodiment, a method for detecting substrate alignment during a printing process may include providing a printing assembly having at least one conductive alignment sensor with a plurality of inductive coils configured to generate an electromagnetic field, providing at least one substrate having at least one conductive portion, aligning the at least one substrate on the printing apparatus such that the conductive alignment sensor and the at least one conductive portion substantially overlap to form electromagnetic field having a direction from the at least one conductive alignment sensor to the at least one conductive portion. The direction of the electromagnetic field with respect to the conductive alignment sensor may form an angle. The method may also include generating an electromagnetic field by applying a current across the plurality of inductive coils, and printing, via the printing apparatus, at least one pattern on the at least one substrate.

In an embodiment, a method of manufacturing a printing apparatus configured to detect alignment of a substrate during a printing process that may include providing a printing assembly having at least one conductive alignment sensor with a plurality of inductive coils configured to generate an electromagnetic field. The method may further include configuring the printing assembly to receive at least one substrate having at least one conductive portion for printing a pattern thereon and align the substrate on the printing assembly such that the plurality of inductive coils and the conductive portion substantially overlap with each other to form an electromagnetic field having a direction from the at least one conductive alignment sensor to the at least one conductive portion. The direction of the electromagnetic field with respect to the conductive alignment sensor may form an angle. The method may also include configuring the at least one alignment sensor to detect a change in the electric current through the plurality of inductive coils when, during the printing process, a change to the angle causes a change in a current through the plurality of inductive coils.

In an embodiment, a substrate for a printing apparatus configured to detect substrate alignment during a printing process may include at least one substrate material configured for printing of a pattern thereon by the printing apparatus and at least one conductive portion arranged within the substrate material. The at least one conductive portion may be arranged to correspond with a plurality of inductive coils of the printing apparatus such that the plurality of inductive coils and the conductive portion substantially overlap with each other to form an electromagnetic field having a direction from the at least one conductive alignment sensor to the at least one conductive portion. The direction of the electromagnetic field with respect to the conductive alignment sensor may form an angle.

### BRIEF DESCRIPTION OF THE DRAWINGS

FIG. 1 depicts an illustrative printing apparatus according to an embodiment.

FIG. 2 depicts another illustrative printing apparatus according to an embodiment.

FIG. 3 depicts various conductive portions of a substrate according to various embodiments.

FIGS. 4A and 4B depict illustrative directions of electromagnetic fields according to various embodiments.

FIG. 5 depicts a flow diagram of a method of detecting substrate alignment during a printing process.

FIG. 6A depicts a flow diagram of a method for constructing a printing apparatus according to an embodiment.

FIG. 6B depicts a flow diagram of an illustrative method of providing a printing assembly according to an embodiment.

FIG. 7 depicts a graphical representation of a method of constructing a printing apparatus according to an embodiment.

FIG. 8 depicts a block diagram of an illustrative computing device according to an embodiment.

### DETAILED DESCRIPTION

This disclosure is not limited to the particular systems, devices and methods described, as these may vary. The terminology used in the description is for the purpose of describing the particular versions or embodiments only, and is not intended to limit the scope.

As used in this document, the singular forms “a.” “an,” and “the” include plural references unless the context clearly dictates otherwise. Unless defined otherwise, all technical and scientific terms used herein have the same meanings as commonly understood by one of ordinary skill in the art. Nothing in this disclosure is to be construed as an admission that the embodiments described in this disclosure are not entitled to antedate such disclosure by virtue of prior invention. As used in this document, the term “comprising” means “including, but not limited to.”

The following terms shall have, for the purposes of this application, the respective meanings set forth below.

A “printing apparatus” refers to an apparatus configured to print and/or deposit a material in a pattern onto a substrate using various printing techniques, such as inkjet or roll-to-roll printing techniques. An illustrative roll-to-roll printing apparatus may include a roller or cylinder imprinted with a pattern. Ink is applied to the roller, and the roller is rolled over the substrate under pressure such that the ink is deposited on the substrate in the pattern imprinted on the roller. Roll-to-roll printing processes may be used to print various types of patterns on substrate materials, including electronic circuits. Illustrative roll-to-roll printing apparatuses include a gravure printing apparatus and a flexographic printing apparatus. Other illustrative printing apparatuses include a screen printing apparatus and an inkjet printing apparatus. An inkjet printing apparatus may include a piezoelectric print head.

A “substrate” refers to a material upon which a pattern is imprinted during a printing process. The substrate may include various materials, including polymer materials, such as polyethylene terephthalate. Other materials may include, without limitation, glass, cellulose (for example, paper), protein (for example, silk), ceramic, metal (for example, stainless steel, metal alloys, or the like), or a composite. The substrate may be formed from films of certain materials or composites. The pattern may be imprinted using one or more ink materials that are deposited on the substrate to form the pattern.

“Ink” refers to a material being deposited on a substrate during the printing process. Ink may include any material capable of being deposited on a substrate, such as conductive, metal based, or non-metal based inks, including, for example, inks for electronic circuits or crystalline silicon for thin film transistor (TFT) displays. Accordingly, inks are not limited to fluids containing pigments or dyes for coloring a surface. In certain applications, multiple inks may be deposited on a single substrate. For example, a TFT may comprise a substrate with one ink layer deposited to form gate electrodes and another ink layer deposited to serve as an insulator.

An “alignment area” refers to an area where a conductive alignment sensor and a conductive portion of a substrate substantially overlap with each other to form an electromagnetic field. The electromagnetic field may have a direction that flows from the conductive alignment sensor to the conductive portion of the substrate in a straight line within the alignment area.

The present disclosure relates generally to systems and methods for detecting a misalignment of a substrate during a printing process, such as a roll-to-roll printing process, using an electromagnetic field. In an illustrative embodiment, a printing apparatus may include a roll-to-roll printing assembly having at least one conductive alignment sensor. The conductive alignment sensor may be configured with a plurality of inductive coils therein to generate an electromagnetic field. When a substrate having a conductive portion passes over (for example, overlaps) the conductive alignment sensor, an electromagnetic field between the inductive coils and the conductive portion is formed. The direction of the electromagnetic field may have a particular angle with respect to the conductive alignment sensor based upon the location of the conductive portion. When a misalignment of the substrate occurs during the printing process, the angle changes, thereby inducing a change in current through the plurality of inductive coils. When this current change is sensed, the printing apparatus recognizes this as a misalignment and directs the printing assembly to stop and/or realign the substrate before continuing.

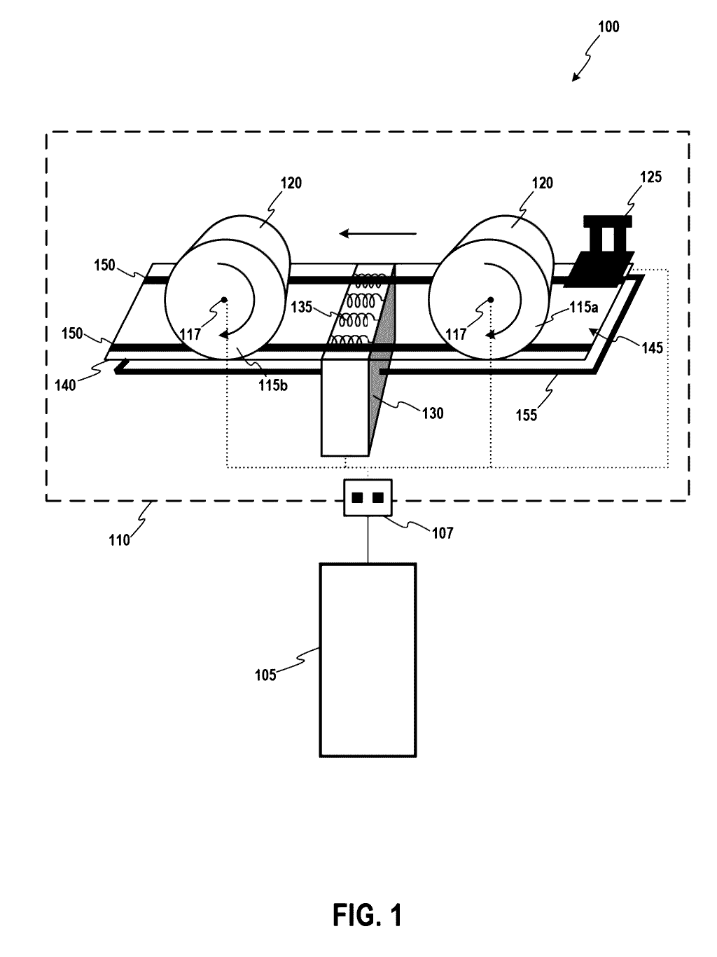

FIG. 1 depicts an illustrative printing apparatus according to an embodiment. As shown in FIG. 1, the printing apparatus 100 may include a printing assembly 110 such as, for example, a roll-to-roll printing assembly. The printing assembly 110 may generally include one or more rollers 115a, 115b, a conductive alignment sensor 130, a control device 107, a substrate alignment assembly 125, and a substrate holder 155. In various embodiments, the printing assembly 110 may be operated by directing a substrate 140 on the substrate holder 155 so that it passes a first roller 115a, the conductive alignment sensor 130, and optionally, the second roller 115b, as will be described in greater detail herein.

The one or more rollers 115a, 115b are not limited by this disclosure, and may include any number of rollers, particularly those used in a roll-to-roll printing assembly. For example, the roll-to-roll printing assembly may have 1, 2, 3, 4, 5, 6, 7, 8, or more rollers. Rollers 115 may be configured to apply an ink to a substrate 140, to imprint a pattern on a substrate, to advance a substrate through the printing apparatus, to reposition a substrate, to redirect a substrate, to receive a substrate in the printing apparatus, to eject a substrate from the printing apparatus, and/or the like. Each roller 115 may be used for imprinting a particular electronic element or portion thereof on the substrate, depositing an ink on the substrate, and/or advancing the substrate. Each roller 115 may be any shape and/or size, which may be independent of a shape and/or a size of another roll. In particular embodiments, each roller 115 may be generally cylindrical in shape and may be sufficiently sized so that the roller can contact the entire width of the substrate 140 during the printing process. Each roller 115 may be formed from one or more materials, such as metal and/or plastic materials.

In various embodiments, each roller 115 may be configured to advance the substrate 140 in a direction. For example, each roller 115 may be configured to move in a clockwise or a counterclockwise direction to effect movement of the substrate 140. Thus, the positioning of each roller 115 may dictate the direction of its movement. For example, if a roller 115 is positioned in contact with a first surface 145 of the substrate 140 (such as the top of the substrate), it may rotate on a center axis 117 in a counterclockwise direction to effect a right-to-left movement of the substrate, as depicted by the arrow in FIG. 1. Furthermore, if a roller 115 is positioned in contact with a second surface of the substrate 140 (such as the bottom of the substrate), it may rotate on the center axis 117 in a clockwise direction to effect the right-to-left movement of the substrate, as depicted by the arrow in FIG. 1. Accordingly, movement of the roller 115 in an opposite direction may cause left-to-right movement of the substrate 140.

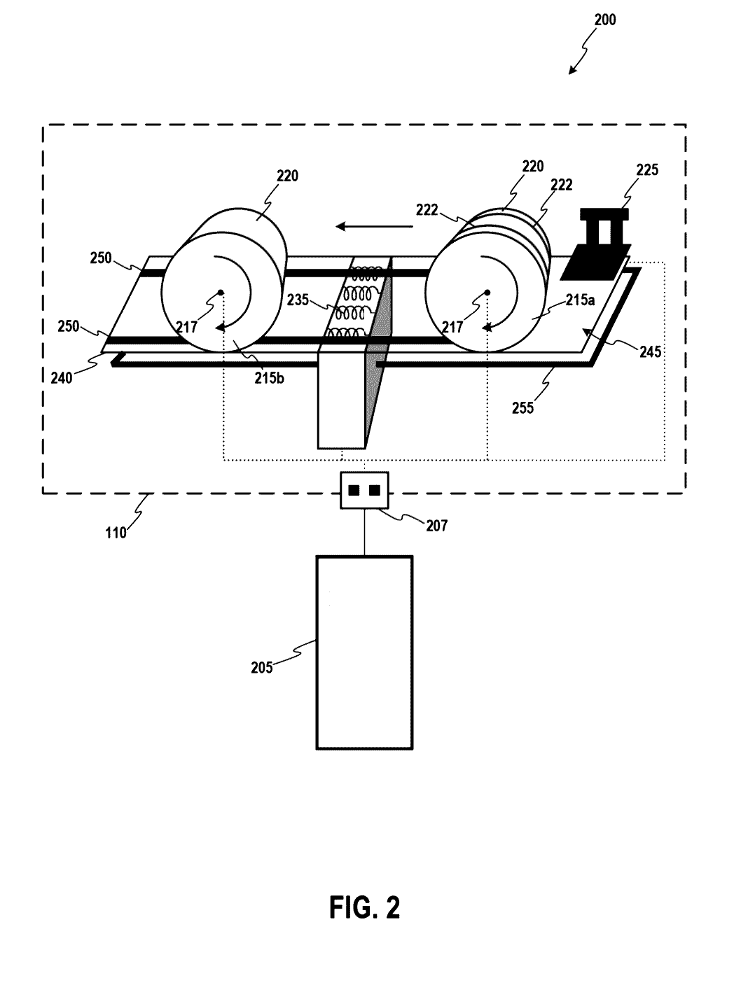

In addition to being configured to advance the substrate 140, each roller 115 may also be configured to apply a pressure to imprint a pattern on the substrate. In some embodiments, the rollers 115a. 115b may be configured as lithographic rollers or the like. Such a roller 115 may generally include a pattern formed on the surface 120 of the roller, which, when pressed against the substrate 140, causes a complementary pattern to form on the substrate. In some embodiments, the rollers 115a, 115b may include an ink or similar marking material on the surface 120, which, when pressed against the substrate 140, transfers the ink to the substrate. In some embodiments, such as the embodiment shown in FIG. 2, the ink or similar marking material may include a material that, when applied to the substrate 240, becomes the conductive portion 250. In such embodiments, the conductive portion 250 may not be pre-applied to the substrate, and must be applied via at least one of the rollers 115 before it can be sensed for alignment.

While only one conductive alignment sensor 130 is depicted herein, the number of conductive alignment sensors is not limited by this disclosure. Accordingly, those with skill in the art will recognize that the printing assembly 110 may include multiple conductive alignment sensors 130 placed throughout to detect alignment of the substrate during various stages of the printing process. In addition, the conductive alignment sensor 130 may be integrated with the substrate holder 155 so that the combined elements function to detect substrate 140 alignment and to hold and/or support the substrate during the printing process.

In various embodiments, the conductive alignment sensor 130 may generally include a plurality of inductive coils 135 that generate an electromagnetic field. An inductive coil, as used herein, is generally a device that generates a magnetic field in response to changes in electric current passing through the coil. The coil includes a number of wire turns around a core. The number of wire turns around the core is not limited by this disclosure, and may include any number of wire turns, such as, for example, 1, 2, 3, 4, 5, 6, 7, 8, or more turns. As current flows through the coil, a magnetic field is produced predominately in the core. Accordingly, the conductive alignment sensor 130 may be connected to a power source (not shown) via at least one lead line that provides an electric current to the plurality of inductive coils 135.

In some embodiments, the conductive alignment sensor 130 may be configured as an in-line Eddy current sensor array. The Eddy-current sensing may include excitation of an excitation coil embedded in a magnetic core, the excitation coil with an electric current having a prescribed frequency. As a result, a time-varying magnetic field at the same frequency is produced, which is detected with a detection coil that is also embedded in the magnetic core. In some embodiments, the excitation coil may be positioned substantially perpendicular to the detection coil in such a manner that, during the printing process described herein, the substrate passes between the two coils, and an electromagnetic matrix is formed by the two coils across a width of the substrate. A spatial distribution of the magnetic field and the field measured by the detection coil is influenced by the proximity and various physical properties (such as, for example, electrical conductivity and magnetic permeability) of nearby materials, such as, for example, the substrate. When the sensor is intentionally placed in close proximity to a material, the physical properties of the material can be detected from measurements of the impedance between the excitation coil and the detection coil. Thus, the in-line Eddy current sensor array may be useful to detect flaws in the substrate, such as, for example, cracks, misprints, and/or the like.

In some embodiments, the conductive alignment sensor 130 may further include a conductive sensor (not shown). The conductive sensor may be configured to sense strain on the substrate 140 when the substrate includes a dotted or dashed conductive portion 150, as described in greater detail herein. The conductive sensor may generally sense strain by measuring the conductivity of the conductive portion 150 of the substrate 140, where the conductive portion has a pattern with a known or an expected conductivity. If the measured conductivity deviates from the known or expected pattern, the conductive sensor will recognize the mismatch as strain on the substrate 140.

In some embodiments, the conductive alignment sensor 130 may be placed in a stationary position such that the substrate 140 passes over a portion of the sensor. In some embodiments, the conductive alignment sensor 130 may be configured to move. Particularly, the conductive alignment sensor 130 may move across a width of the substrate 140 such that the conductive alignment sensor moves in a direction that is substantially perpendicular to a longitudinal forward movement of the substrate during the printing process. Such a movement of the conductive alignment sensor 130 may be particularly useful in situations in which the width of the substrate 140 is longer than the conductive alignment sensor. Thus, the conductive alignment sensor 130 may move to ensure proper monitoring and detection of substrate 140 alignment. In some embodiments, the conductive alignment sensor 130 may be affixed to a print head such that the conductive alignment sensor moves with the print head as the print head deposits ink onto the surface of the substrate 140.

In various embodiments, the alignment assembly 125 may generally be configured to position the substrate 140 on the printing assembly 110. The alignment assembly 125 may include, for example, various components, such as a linear stage guide, a linear motor, a motor, clamps, a prehensile apparatus, and/or the like to effect a repositioning movement of the substrate 140 and/or components of the printing assembly 110 to align the substrate with the printing apparatus. The linear stage guide may generally be a device that is configured to precisely position the substrate along a single axis. The linear motor may generally be a motion control element that imparts one or more linear forces to the substrate for which compensating (such as, for example, correcting or other reacting) control is provided according to various embodiments described herein. In some embodiments, the alignment assembly 125 may be integrated with the substrate holder 155. In some embodiments, the software application may transmit one or more alignment signals to the alignment assembly 125 in response to receiving information that the substrate 140 is not properly aligned or is misaligned. Such alignment signals may instruct the alignment assembly 125 to reposition the substrate 140.

Misalignment of the substrate 140 on the printing assembly 110 may be caused by a wide variety of factors. For example, misalignment may occur due to thermal expansion and/or deformation of the substrate 140 and/or various components of the printing assembly 110. In another example, the substrate 140 and/or a roll of substrate may be mounted in a misaligned position, thereby causing misalignment. In yet another example, misalignment may be due to various components of the printing assembly 110, particularly mechanical components, such as holders, clamps, the substrate holder 155, and/or the like moving during the printing process. In another example, misalignment may be due to movement of the substrate 140 and/or the substrate roll as a result of contact with various components of the printing assembly 110, such as a doctor blade, an impression roller, holders, clamps, or the substrate holder 155. The printing apparatus 100 may be configured to provide high detection sensitivity, continuous monitoring, and reduced mechanical error compared to conventional methods and systems to avoid and/or correct misalignment of the substrate 140 during a printing process.

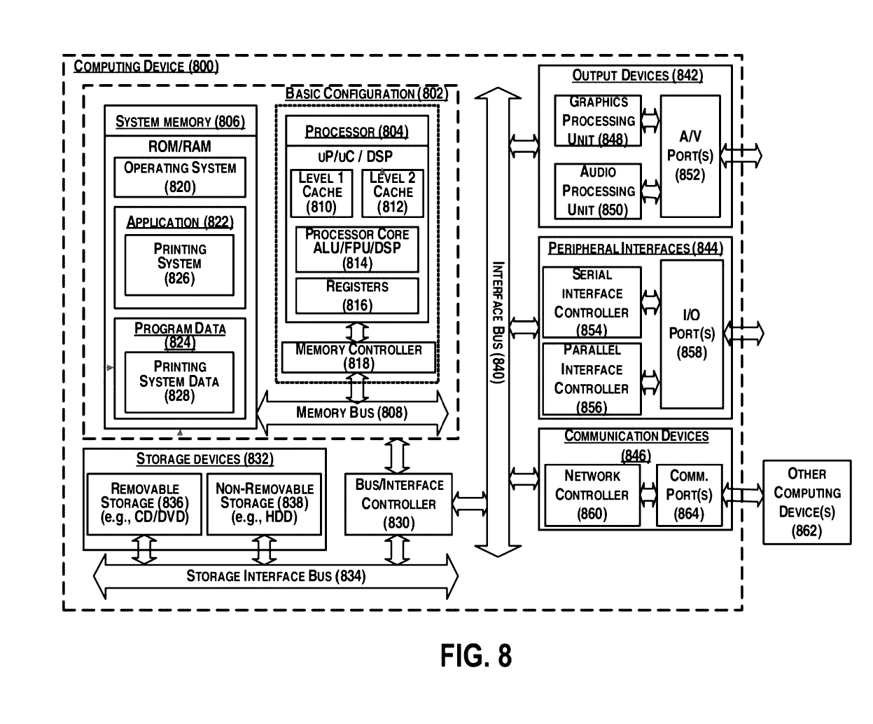

In various embodiments, the control device 107 may be in operable communication with at least the conductive alignment sensor 130, the substrate alignment assembly 125, and/or the rollers 115a, 115b. The control device 107 may generally have at least one processor and at least one system memory, such as, for example, the computing device 800, the processor 804, and the system memory 806 described in relation to FIG. 8 herein. The control device 107 may be configured to receive information from the conductive alignment sensor 130, the substrate alignment assembly 125, and/or the rollers 115a, 115b, including information regarding characteristics associated with an electromagnetic field, electric currents, rotational velocity, and/or the like. The control device 107 may be associated with one or more programming instructions configured to manage and/or control the printing assembly 110, associated data, and components thereof, as described herein. For example, a software application operating on the control device 107 may receive information obtained by the alignment sensor 130 and/or the rollers 115a, 115b relating to at least one characteristic of the electromagnetic field, the electric current, the rotational velocity of the rollers, and/or the like. The software application may feed the information into a process configured to determine whether the substrate 140 is aligned on the printing assembly 110, as described in greater detail herein. The software application may also provide instructions to the substrate alignment assembly 125 and/or the rollers 115a, 115b to stop and/or realign the substrate 140 if the substrate is misaligned, as described in greater detail herein. The instructions may be provided via a stop signal and/or a realignment signal to the printing assembly 110 and/or components thereof.

In various embodiments, the printing assembly 110 may be in operable communication with a computing device 105. In some embodiments, the printing assembly 110 may in operable communication with the computing device 105 via the control device 107. The computing device 105 may generally have at least one processor and at least one system memory, such as, for example, the computing device 800, the processor 804, and the system memory 806 described in relation to FIG. 8 herein. The computing device 105 may operate to execute software configured to manage and/or control the printing assembly 110, associated data, and components thereof, as described herein. In an embodiment, the computing device may control the printing assembly 110 and/or components thereof directly. In other embodiments, the computing device may control the printing assembly 110 and/or components thereof through the control device 107.

In various embodiments, if the computing device 105 determines that the substrate 140 is not properly aligned, the computing device may operate to control the printing assembly 110 and/or components thereof. For example, the computing device 105 may communicate a stop signal to the rollers 115a. 115b and/or a realignment signal to the substrate alignment assembly 125 in response to receiving information indicating that the substrate 140 is misaligned, as described in greater detail herein.

The printing apparatus 100, 200 may be configured to print various components, such as electronic components. Illustrative components may include, but are not limited to, passive electrical components, passive optical components, active electronic components, optoelectronic components, sensors, indicators, light emitting diodes (LEDs), organic light emitting diodes (OLEDs), organic light emitting diode signage, organic transistor circuits, electronic circuits, multilaver electronic circuits, memories, memory elements, memory devices, solar cells, fuel cells, miniaturized fuel cells, optical waveguides, optical microelectromechanical systems (MEMS), arrays, optical read-only memory (OROM) elements (such as, for example, hot embossed OROM, OROM with mobile reader, and the like), transistors, organic field-effect transistors (O-FETs), circuits, electronic circuits for sensors, electronic devices for sensors, radio frequency identification (RFID) components, biocompatible electronic elements, batteries, capacitors, displays (such as, for example, active matrix backplanes), flexible displays, and nanoscale photovoltaics. Examples of passive electrical and optical components may include wirings, resistors, conductors (such as, for example, dielectrics), inductors, diffractive optic elements, light guides, and OROMs. Examples of active electronics and optoelectronic components may include diodes, transistors. LEDs and solar cells.

The printing apparatus 100, 200 described in FIGS. 1 and 2 are merely illustrative examples, and thus embodiments not specifically described herein are also contemplated. Accordingly, any printing system and/or apparatus that may operate according to embodiments described herein are contemplated. Examples of such printing apparatuses may include, but are not limited to, an inkjet printing apparatus, a screen printing apparatus, a nanoimprinting apparatus, a lithographic printing apparatus, an offset lithographic printing apparatus, a UV lithographic printing apparatus, a gravure printing apparatus, an offset gravure printing apparatus, and a flexographic printing apparatus.

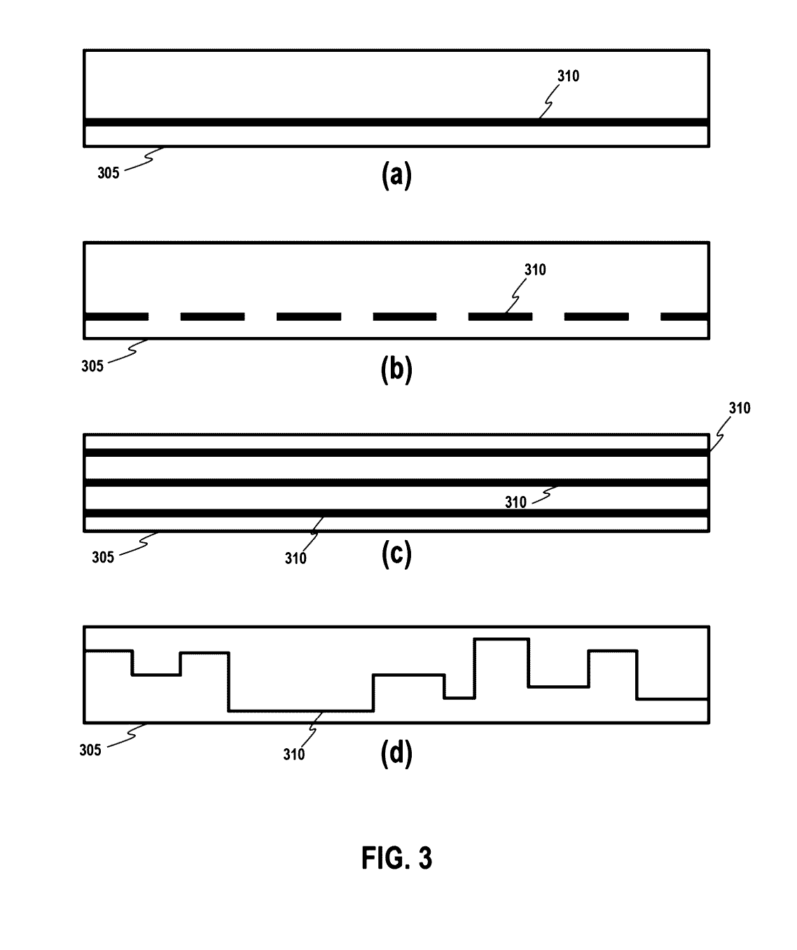

FIG. 3 depicts various substrates 305 according to various embodiments. In some embodiments, the substrate 305 may include various materials, such as, for example, polyethylene terephthalate (PET), polyethylene naphthalate, polyimide, glass, ceramic, a polymer, metal, silicon, cellulose (paper), a composite material, a laminate material, or a combination thereof. One illustrative metal-based substrate is a film or sheet of stainless steel. In some embodiments, the substrate 305 may be configured to receive one or more materials thereon during the printing process, as described herein. Thus, for example, the substrate 305 may be configured to receive at least one electronic element and the one or more conductive portions 310. The size of the substrate 305 is not limited by this disclosure, and may have any dimensions. The substrate 305 may generally be flexible in nature, and in some embodiments, may be capable of being rolled into a roll of substrate material.

The substrate 305 may include one or more conductive portions 310. In some embodiments, the conductive portion 310 may extend in a substantially longitudinal direction along a length of the substrate 305. In some embodiments, the conductive portion 310 may be arranged at an edge of the substrate 305. However, embodiments are not limited to such configurations, as the conductive portion 310 may be arranged at any location on or within the substrate 305 that is capable of functioning according to various embodiments herein. The conductive portion 310 may further be arranged on the substrate in any pattern, such as, for example, (a) a straight line, (b) a dashed line, (c) a plurality of lines, or (d) a step line. Arrangements of the conductive portion 310 shown herein are merely illustrative. Other patterns not specifically mentioned herein may also be used within the scope of this disclosure. The conductive portion 310 may vary in dimensional shape and size, but may generally be in a shape, size, pattern, and location that allows the substrate 305 to be recognized as aligned or misaligned, as described in greater detail herein. Furthermore, the conductive portion 310, when in a dashed line (as shown in part (b)) or a dotted line (not shown), may have a gap between each dash or dot. In various embodiments, each gap may vary. In some embodiments, the gaps may be equal in size. In other embodiments, each gap may have a varying size. In embodiments where the conductive portion 310 is a dashed or dotted line, a conductive sensor may be used to sense strain, as described in greater detail herein. Strain is sensed by using conductivity to detect alignment, stretch of the substrate, and/or the like. For example, a conductive portion 310 that is a dashed or dotted line has a known pattern. As the sensor is sensing the conductivity of the conductive portion 310 of the substrate, the conductivity should provide a pattern that corresponds to the known pattern. If the pattern deviates from the known or expected pattern, the sensor will recognize the mismatch as a misalignment and/or strain.

The conductive portion 310 may be made of any conductive material. Illustrative conductive materials used for the conductive portion 310 may include transition metals, nitrides of transition metals, refractory metals, nitrides of refractory metals, and noble metals. Specific examples of conductive materials may include, but are not limited to, titanium, tantalum, tungsten, molybdenum, hafnium, niobium, nickel, palladium, platinum, rhenium, ruthenium, iridium, and combinations thereof. Examples of metal nitrides may include titanium nitride, tantalum nitride, tungsten nitride, and molybdenum nitride.

In some embodiments, the substrate 305 may incorporate a conductive strain sensor (not shown). The conductive strain sensor may generally be configured to sense strain on the substrate. This may be completed by measuring electrical field induced strain. As previously described herein, strain may be sensed by measuring the conductivity of the conductive portion 310, where the conductive portion has a pattern with a known or an expected conductivity. If the measured conductivity deviates from the known or expected pattern, the mismatch will be recognized as strain on the substrate 305.

Referring back to FIG. 1, the misalignment of the substrate 140 and the detection thereof by the conductive alignment sensor 130 can be explained by an application of Faraday's law of induction. According to the Faraday's law of induction that is applicable to a coil of thin wire (such as the plurality of inductive coils 135), any change in a magnetic environment of the coil of wire will cause an electromotive force EMF(ν) to be induced in the coil. Accordingly, the induced EMF(ν) in the coils 135 is equal to the negative of the rate of change of magnetic flux times the number of turns in the coil, as represented in the following equation when there is only one turn:

$$EMF ( v ) = - \frac{d φ}{d t} = - \int \frac{d ( \vec{{B}_{r}} \times \vec{A} )}{d t}$$

where φ represents magnetic flux and A represents the area of the coil. Notably, the EMF(ν) of the coils 135 are characterized in that:

EMF(ν)∝φ∝\vec{Bᵣ}×\vec{A}∝I

where I is the current. That is, the electromotive force (EMF) is in direct proportion to the current I flowing through the coils, which is the relationship that can be adopted for determining a misalignment of the substrate 140.

Moreover, it is known that an electric field will be induced between two objects of different electric potentials. According to Gauss's law, a charge will be induced and generated on the coils 135 when the conductive portion 150 of the substrate 140 is placed in the electromagnetic field. In addition, when the electromagnetic field is a time varying electromagnetic field from an AC source, the charges will be induced to flow on the coils 135 according to the variation of the electromagnetic field as the induction current represented by the following equation:

$$i = ɛ A \frac{d E}{d t}$$

where ε is the dielectric constant, A is the effective area of the metal plate, and E is the time varying electric field. The induction current of the coils 135 is characterized in that:

i∝E∝V

where V is the potential difference between the coils and the conductive portion 150. Thus, the induction current is in direct proportion to the potential difference, which is the relationship that can be adopted for detecting misalignment of the substrate 140.

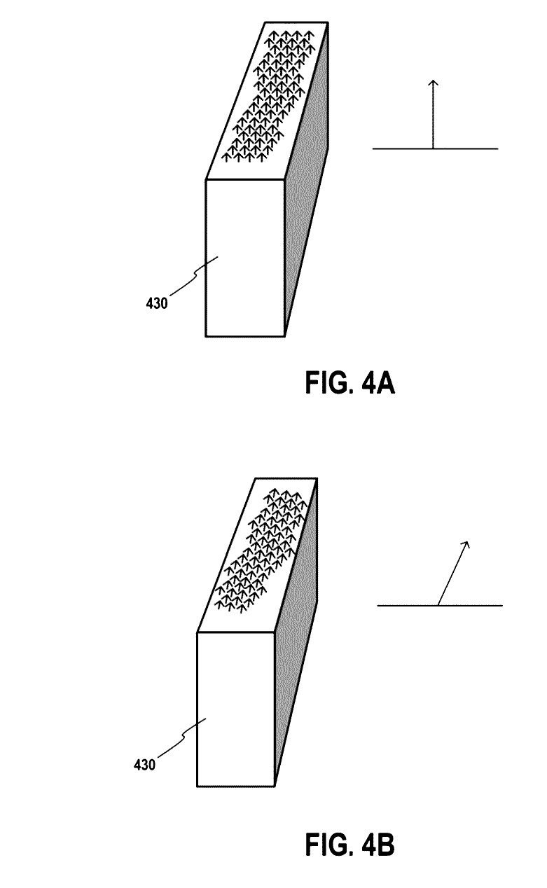

FIGS. 4A and 4B depict how a misalignment causes a change in an angle created by the direction of the electromagnetic field with respect to the conductive alignment sensor 430, which, in turn, induces a change in the current through the coils 135 (FIG. 1). The change in the current through the coils may be any change, and is not limited by this disclosure. Illustrative examples of change in current may include, but are not limited to, a directional change, a change in flux density, and/or the like. The conductive portion 310 of the substrate 305 (FIG. 3) causes the direction of the electromagnetic field to flow directly from the conductive alignment sensor 430 to the conductive portion. Thus, the direction of the electromagnetic field with respect to the conductive alignment sensor 430 results in an angle. When the substrate is properly aligned, the angle may generally be in a first direction, as shown in FIG. 4A. For illustrative purposes only, the angle is about 90° as shown in FIG. 4A because the direction electromagnetic field is perpendicular with respect to the alignment sensor 430 because the alignment sensor and the conductive portion of the substrate are substantially parallel with respect to each other. When a misalignment occurs, the movement of the conductive portion of the substrate will cause the direction of the electromagnetic field to change so that it remains a direct line from the alignment sensor to the conductive portion, as shown in FIG. 4B. Thus, the angle changes, which induces a current change in the coils, which is recognized by the control device 107 (FIG. 1) as an indication of the misalignment. The control device 107 and/or the computing device 105 (FIG. 1) may be configured to calculate the angle of the direction of the magnetic field based on the induced current change, and may further be configured to determine a precise movement of the substrate that will cause the substrate to realign, as described in greater detail herein. In some embodiments, the control device 107 and/or the computing device 105 may be sufficiently configured to detect miniscule changes in the induced current change.

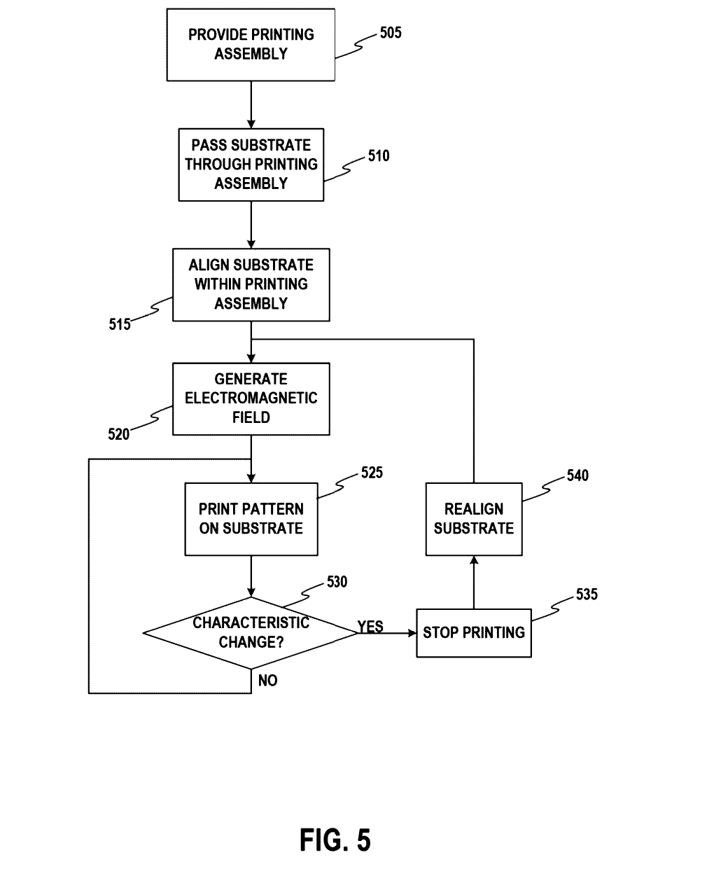

FIG. 5 depicts a flow diagram of a method of detecting substrate alignment during a printing process. A printing assembly may be provided 505 that includes a conductive alignment sensor. For example, a roll-to-roll printing apparatus may include a substrate holder configured to hold and/or support a substrate. The substrate holder may be connected to or integrated with the conductive alignment sensor, which includes a plurality of inductive coils and is configured to generate an electromagnetic field, as described in greater detail herein.

The substrate may be provided and passed 510 through the printing assembly in such a manner that the printing assembly deposits materials on the substrate, as described in greater detail herein. The substrate may be aligned 515 within the printing assembly such that the plurality of inductive coils and a conductive portion of the substrate substantially overlap with each other to form an electromagnetic field having a direction that flows from the conductive alignment sensor to the conductive portion, and which is generated 520 by the inductive coils. Generating 520 the electromagnetic field may include applying a current across the plurality of inductive coils, as described herein. In some embodiments, the electric current may be an alternating current. In some embodiments, the electric current may have a frequency of about 100 kilohertz (kHz) to about 100 megahertz (MHz). For example the frequency may be about 100 kHz about 200 kHz, about 300 kHz, about 500 kHz, about 700 kHz, about 800) kHz, about 1 MHz, about 5 MHz, about 10 MHz, about 50 MHz, about 100 MHz, or any value or range between any two of these values (including endpoints). In some embodiments, the electric current may be about 1 milliamp (mA) to about 500 mA, including about 1 mA, about 5 mA, about 10 mA, about 25 mA, about 50 mA, about 100 mA, about 200 mA, about 250 mA, about 500 mA, or any value or range between any two of these values (including endpoints).

During the printing process, a pattern may be printed 525 on the substrate and the electric current through the coils may be monitored. For example, the conductive alignment sensor may detect a baseline electric current induced through the coils when the substrate is initially placed in an aligned position. The conductive alignment sensor may continuously monitor the electric current through the coils during the printing process to determine whether the electric current deviates from the baseline electric current. If such a characteristic change is detected, the printing process may be stopped 535 so that the substrate can be realigned 540 and the printing 525 can continue. In some embodiments, the process may not stop. Rather, the substrate is realigned 540 on the fly as the printing process continues. In such embodiments, the printing apparatus may be configured to mark or tag the portion of the substrate that was misaligned during printing to ensure the substrate is removed or corrected during a quality control process.

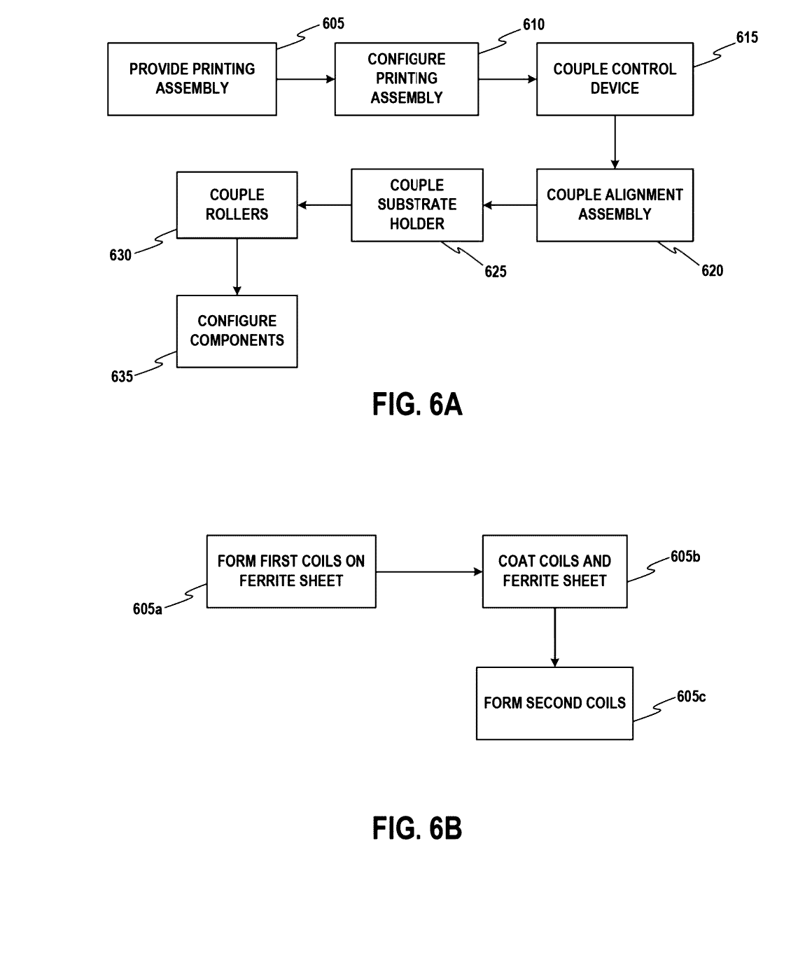

FIG. 6A depicts a flow diagram of a method for constructing a printing apparatus according to an embodiment. The printing assembly may be provided 605. In some embodiments, any printing assembly that is configured to print may be provided 605. FIG. 6B depicts a flow diagram of various steps for providing 605 the printing assembly according to an embodiment. Particularly, FIG. 6B relates to providing 605 the conductive alignment sensor portion of the printing assembly. A first set of coils may be formed 605a on a ferrite sheet. The first set of coils may include any number of coils, and is not limited by this disclosure. For example, the first set of coils may have 1, 2, 3, 4, 5, 6, 7, 8, or more coils. The coils may be formed from any electrical conductor material, such as, for example, a copper wire. Forming 605a may generally include deposition of the coil on the ferrite sheet, which can be completed by any method of deposition, including known line patterning, masking, and/or etching techniques. The coil may be a single-layer coil or may include multiple turns in multiple layers. Coils may be stacked on top of each other or may be placed side-by-side. The ferrite sheet is also not limited by this disclosure, and may generally be any mixed oxide sheet having one or more metal ions and one or more oxygen ions. Illustrative examples of ferrite may include, but are not limited to, magnetite (Fe₃O₄), maghemite (Fe₂O₃), manganese ferrite, zinc ferrite, copper ferrite, chrome ferrite, cobalt ferrite, or nickel ferrite. The ferrite sheet may be used as a magnetic core or a substrate for the coils.

The coils and the ferrite sheet may be coated 605b. In some embodiments, the coils and the ferrite sheet may be coated 605b with a dielectric material. Illustrative dielectric materials may include, but are not limited to a silicone polymer, an epoxy, polyimide, polyethylene, polypropylene, polyphenylene oxide, polysulphone, a sol gel material, a ceramer, silicon dioxide, aluminum oxide, zirconium oxide, a metal oxide insulator, or a combination thereof.

A second set of coils may be formed 605c on the coated first coils on the ferrite sheet. In some embodiments, the second set of coils may be formed 605c in a direction that is substantially perpendicular to the direction of the first set of coils. As with the first set of coils, the second set of coils may also include any number of coils, and is not limited by this disclosure. For example, the second set of coils may have 1, 2, 3, 4, 5, 6, 7, 8, or more coils. The coils may be formed from a wire, such as a copper wire. However, the materials used for forming the wire are not limited by this disclosure and can include any substance, particularly substances that are known in the art as useful for electrical conductivity. Forming 605c may generally include deposition of the coil on the coated first set of coils on the ferrite sheet, which can be completed by any method of deposition, including known line patterning, masking, and/or etching techniques. The coil may be a single-layer coil or may include multiple turns in multiple layers. Coils may be stacked on top of each other or may be placed side-by-side.

Referring back to FIG. 6A, the printing assembly may be configured 610 for printing as described herein. In some embodiments, the printing assembly may be configured 610 to receive at least one substrate having at least one conductive portion, as described herein. The printing assembly may further be configured 610 to print a pattern on the substrate, as described in greater detail herein. In some embodiments, the printing assembly may further be configured 610 to align the substrate on the printing assembly so that the inductive coils in an alignment sensor portion of the printing assembly and the conductive portion of the substrate substantially overlap with each other. The overlapping may form an electromagnetic field, as described in greater detail herein. In some embodiments, the alignment sensor portion of the printing assembly may further be configured to continuously monitor and detect a change in the electric current through the plurality of coils during a printing process, as described in greater detail herein.

In various embodiments, a control device may be coupled 615 to the printing assembly. The control device may generally be coupled 615 in such a manner that it can send signals to the printing assembly and receive signals from the printing assembly. Such coupling 615 may be via a wired or a wireless connection.

In various embodiments, a substrate alignment assembly may be coupled 620 to the printing assembly. The substrate alignment assembly may generally be coupled 620 in such a manner that it can position, align, and/or realign the substrate on the printing assembly.

In various embodiments, a substrate holder may be coupled 625 to the printing assembly. The substrate holder may generally be coupled 625 in such a manner that it can hold and/or support the substrate during the printing process, as described in greater detail herein. In some embodiments, the substrate holder may be integrated with the conductive alignment sensor. For example, the conductive alignment sensor may be arranged on the substrate holder.

In various embodiments, one or more rollers may be coupled 630 to the printing assembly. The one or more rollers may generally be coupled 630 in such a manner that they can advance the substrate and/or apply one or more materials or impressions on the substrate, as described in greater detail herein.

The various components of the printing assembly may further be configured 635 for various printing processes as described in greater detail herein. For example, the control device may be configured 635 to receive information from the conductive alignment sensor and/or the rollers indicating that the substrate is aligned or not aligned on the printing assembly. The control device may further be configured 635 to communicate at least one stop signal to the printing assembly upon receiving information that the substrate is not aligned. The control device may be configured 635 to communicate such a signal to the rollers and/or the substrate alignment assembly to stop the substrate, as described in greater detail herein. The control device may also be configured 635 to communicate a realignment signal to the printing assembly upon receiving information that the substrate is not aligned. The control device may be configured 635 to communicate such a signal to the rollers and/or the substrate alignment assembly to realign the substrate, as described in greater detail herein.

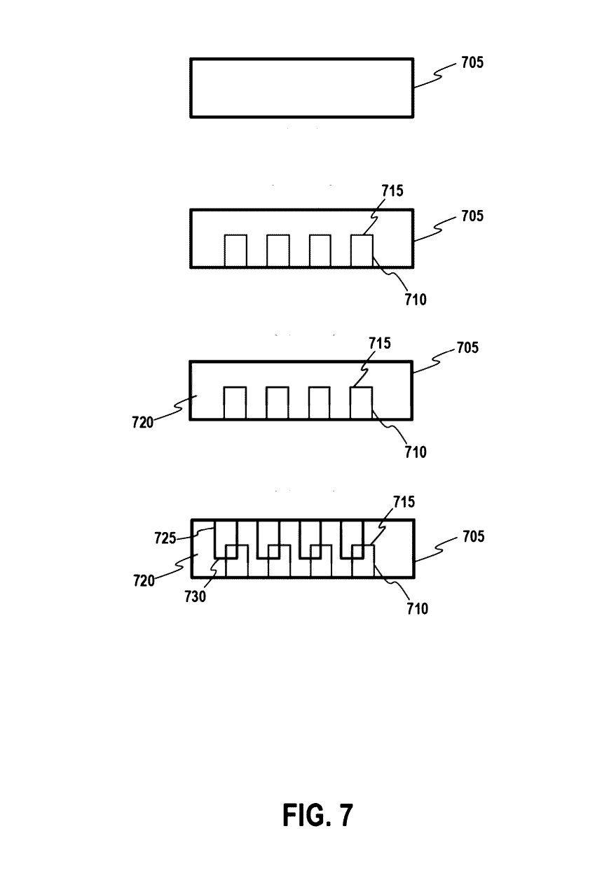

FIG. 7 depicts a graphical representation of the method described herein with respect to FIGS. 6A and 6B. Particularly, a ferrite sheet 705 is provided, and a first plurality of induction coils 715 and lead lines 710 (to provide a current to the induction coils) are deposited on the ferrite sheet. An insulator coating 720 is placed over the ferrite sheet 705, the first plurality of induction coils 715, and the lead lines 710. A second plurality of induction coils 730 and lead lines 725 are deposited over the insulator coating 720, as described herein.

FIG. 8 depicts an illustrative computing device 800 that may be used to contain or implement program instructions for controlling aspects of a printing system according to some embodiments described herein. In a very basic configuration 802, the computing device 800 typically includes one or more processors 804 and a system memory 806. A memory bus 808 may be used for communicating between processor 804 and system memory 806.

Depending on the desired configuration, the processor 804 may be of any type including but not limited to a microprocessor (μP), a microcontroller (μC), a digital signal processor (DSP), or any combination thereof. The processor 804 may include one more levels of caching, such as a level one cache 810 and a level two cache 812, a processor core 814, and/or registers 816. The processor core 814 may include an arithmetic logic unit (ALU), a floating point unit (FPU), a digital signal processing core (DSP Core), or any combination thereof. A memory controller 818 may also be used with the processor 804. In some implementations, the memory controller 818 may be an internal part of the processor 804.

Depending on the desired configuration, the system memory 806 may be of any type, including, but not limited to, volatile memory (such as RAM), non-volatile memory (such as ROM, flash memory, etc.) or any combination thereof. The system memory 806 may include an operating system 820, one or more applications 822, and program data 824. An application 822 may include a printing system manager 826 that is arranged to manage aspects of a printing apparatus in reference to FIGS. 1-2. Program data 824 may include data obtained from operation of a printing apparatus, conductive alignment sensors (for example, 130), controllers (for example, 107), alignment assemblies (for example, 125), rollers (for example, 115), and elements in communication thereto 828. In some embodiments, the application 822 may be arranged to operate with program data 824 on the operating system 820 such that certain components of the printing system, such as a control device, printing apparatus, and/or alignment assembly, may operate according to some embodiments described herein. This described basic configuration 802 is illustrated in FIG. 8 by those components within the inner dashed line.

The computing device 800 may have additional features or functionality, and additional interfaces to facilitate communications between the basic configuration 802 and any required devices and interfaces. For example, a bus/interface controller 830 may be used to facilitate communications between the basic configuration 802 and one or more data storage devices 832 via a storage interface bus 834. The data storage devices 832 maxy be removable storage devices 836, non-removable storage devices 838, or a combination thereof. Examples of removable storage and non-removable storage devices include magnetic disk devices such as flexible disk drives and hard-disk drives (HDD), optical disk drives such as compact disk (CD) drives or digital versatile disk (DVD) drives, solid state drives (SSD), and tape drives to name a few. Example computer storage media may include volatile and nonvolatile, removable and non-removable media implemented in any method or technology for storage of information, such as computer readable instructions, data structures, program modules, or other data.

The system memory 806, the removable storage devices 836, and the non-removable storage devices 838 are examples of computer storage media. Computer storage media includes, but are not limited to, RAM, ROM, EEPROM, flash memory or other memory technology, CD-ROM, digital versatile disks (DVD) or other optical storage, magnetic cassettes, magnetic tape, magnetic disk storage or other magnetic storage devices, or any other medium which may be used to store the desired information and which may be accessed by the computing device 800. Any such computer storage media may be part of the computing device 800.

The computing device 800 may also include an interface bus 840 for facilitating communication from various interface devices (for example, output devices 842, peripheral interfaces 844, and communication devices 846) to the basic configuration 802 via the bus/interface controller 830. Illustrative output devices 842 include a graphics processing unit 848 and an audio processing unit 850, which may be configured to communicate to various external devices such as a display or speakers via one or more A/V ports 852. Example peripheral interfaces 844 include a serial interface controller 854 or a parallel interface controller 856, which may be configured to communicate with external devices such as input devices (for example, keyboard, mouse, pen, voice input device, touch input device, etc.) or other peripheral devices (for example, printer, scanner, etc.) via one or more I/O ports 858. An illustrative communication device 846 includes a network controller 860, which may be arranged to facilitate communications with one or more other computing devices 862 over a network communication link via one or more communication ports 864.

The network communication link may be one example of a communication medium. Communication media may typically be embodied by computer readable instructions, data structures, or program modules, and may include any information delivery medium. A “modulated data signal” may be a signal that has one or more of its characteristics set or changed in such a manner as to encode information in the signal. By way of example, and not limitation, communication media may include wired media such as a wired network or direct-wired connection, and wireless media such as acoustic, radio frequency (RF), microwave, infrared (IR) and other wireless media.

The computing device 800 may be implemented as a portion of a small-form factor portable (or mobile) electronic device such as a cell phone, a personal data assistant (PDA), a personal media player device, a wireless web-watch device, a personal headset device, an application specific device, or a hybrid device that include any of the above functions. The computing device 800 may also be implemented as a personal computer including both laptop computer and non-laptop computer configurations.

### EXAMPLES

### Example 1

### Gravure Printing Apparatus

A gravure roll-to-roll printing apparatus will operate to print a pattern arranged on a gravure cylinder onto a roll of 100 cm wide polyimide-based substrate having a conductive portion running in a straight line along a first edge of the substrate. The substrate will be mounted on a roller configured to turn in a clockwise direction to unroll the substrate during the printing process. The substrate will be directed along a Newport Linear Translation Stage Guide (Newport Corporation, Irvine, Calif.) to align with a gravure cylinder. The stage guide will be configured to move in the y and theta directions with respect to a cylindrical coordinate system. A Parker-Hannifin linear motor (Parker-Hannifin Corp., Cleveland, Ohio) will be configured to move the stage guide in the x direction with respect to the cylindrical coordinate system. The gravure cylinder, the stage guide, and the linear motor will be in operable communication with a printing system control device configured to execute a software application configured to monitor and control operational aspects of the printing system and the aforementioned components.

The gravure printing system will further include a conductive alignment sensor having 5 inductive coils therein. The inductive coils will be powered with an alternating current at 100 mA and having a frequency of about 800 kHz. The substrate will be aligned over the conductive alignment sensor such that the conductive line passes over the 5 inductive coils to generate an electromagnetic field that is in a direction substantially perpendicular to the top surface of the substrate.

The control device will monitor the inductive coils in the conductive alignment sensor such that they remain at 100 mA and 800 kHz. If a deviation of 1 mA and/or 1 kHz is detected, the control device will recognize this as a misalignment of the substrate and will send a signal to the gravure cylinder to stop rotating and a signal to the stage guide to realign the substrate.

The substrate will be mounted and aligned within the printing system with the gravure cylinder positioned slightly above and out of contact with the substrate. The gravure cylinder will be lowered onto the substrate and loaded with a pneumatic compression system to a weight of about 20 kilograms (kg). The coils in the conductive alignment sensor will be checked prior to printing such that the current is 100 mA and at 800 kHz. If they are, the control device will recognize that the substrate is properly aligned, and will send a signal to the printing system to commence printing. A doctor blade will be placed against the gravure cylinder, the gravure cylinder will be inked, and the substrate will be moved under the rotating gravure cylinder using the linear motor to transfer the ink to the substrate.

During the printing process, if the control device determines that the substrate is misaligned, it may communicate a stop signal to the gravure roll-to-roll printing system and/or various components thereof to stop printing. The control device may transmit one or more signals to the gravure roll-to-roll printing system and/or various components thereof to adjust the position of the substrate until it is realigned, and then the control device will re-check the position of the substrate to confirm that it is realigned. If the substrate is properly aligned, the control application may transmit a start signal to the gravure roll-to-roll printing system and/or the various components thereof to restart the printing process.

### Example 2

### Substrate for a Roll-to-Roll Printing Process

A substrate that is particularly suitable for a roll-to-roll printing apparatus that uses electromagnetic detection of substrate misalignment will be in a roll form. Particularly, the substrate is made from a flexible polyethylene terephthalate (PET) based material and, when unrolled, is 1000 meters by 1 meter. To minimize the costs associated with producing the substrate, it has a thin, 1 cm wide dashed line running along its length, as shown in FIG. 3(b). The line is located 10 cm from the edge of the substrate, and is made of nickel. The nickel strip allows the substrate to be sensed for alignment during a roll-to-roll printing process, where the substrate is unrolled and passed through a printing apparatus that prints electronic elements on the substrate, monitors the substrate for proper alignment, and outputs the substrate for additional processing, such as cutting, sheeting, and/or the like.

In the above detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be used, and other changes may be made, without departing from the spirit or scope of the subject matter presented herein. It will be readily understood that the aspects of the present disclosure, as generally described herein, and illustrated in the Figures, can be arranged, substituted, combined, separated, and designed in a wide variety of different configurations, all of which are explicitly contemplated herein.

The present disclosure is not to be limited in terms of the particular embodiments described in this application, which are intended as illustrations of various aspects. Many modifications and variations can be made without departing from its spirit and scope, as will be apparent to those skilled in the art. Functionally equivalent methods and apparatuses within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, reagents, compounds, compositions or biological systems, which can, of course, vary. It is also to be understood that the terminology used herein is for the purpose of describing particular embodiments only, and is not intended to be limiting.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (for example, bodies of the appended claims) are generally intended as “open” terms (for example, the term “including” should be interpreted as “including but not limited to,” the term “having” should be interpreted as “having at least,” the term “includes” should be interpreted as “includes but is not limited to,” et cetera). While various compositions, methods, and devices are described in terms of “comprising” various components or steps (interpreted as meaning “including, but not limited to”), the compositions, methods, and devices can also “consist essentially of” or “consist of” the various components and steps, and such terminology should be interpreted as defining essentially closed-member groups. It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (for example, “a” and/or “an” should be interpreted to mean “at least one” or “one or more”); the same holds true for the use of definite articles used to introduce claim recitations. In addition, even if a specific number of an introduced claim recitation is explicitly recited, those skilled in the art will recognize that such recitation should be interpreted to mean at least the recited number (for example, the bare recitation of “two recitations,” without other modifiers, means at least two recitations, or two or more recitations). Furthermore, in those instances where a convention analogous to “at least one of A, B, and C, et cetera” is used, in general such a construction is intended in the sense one having skill in the art would understand the convention (for example, “a system having at least one of A, B, and C” would include but not be limited to systems that have A alone, B alone, C alone, A and B together, A and C together, B and C together, and/or A, B, and C together, et cetera). In those instances where a convention analogous to “at least one of A, B, or C, et cetera” is used, in general such a construction is intended in the sense one having skill in the art would understand the convention (for example, “a system having at least one of A, B, or C” would include but not be limited to systems that have A alone, B alone, C alone, A and B together, A and C together, B and C together, and/or A, B, and C together, et cetera). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

In addition, where features or aspects of the disclosure are described in terms of Markush groups, those skilled in the art will recognize that the disclosure is also thereby described in terms of any individual member or subgroup of members of the Markush group.

As will be understood by one skilled in the art, for any and all purposes, such as in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, et cetera As a non-limiting example, each range discussed herein can be readily broken down into a lower third, middle third and upper third, et cetera As will also be understood by one skilled in the art all language such as “up to,” “at least,” and the like include the number recited and refer to ranges which can be subsequently broken down into subranges as discussed above. Finally, as will be understood by one skilled in the art, a range includes each individual member. Thus, for example, a group having 1-3 cells refers to groups having 1, 2, or 3 cells. Similarly, a group having 1-5 cells refers to groups having 1, 2, 3, 4, or 5 cells, and so forth.

Various of the above-disclosed and other features and functions, or alternatives thereof, may be combined into many other different systems or applications. Various presently unforeseen or unanticipated alternatives, modifications, variations or improvements therein may be subsequently made by those skilled in the art, each of which is also intended to be encompassed by the disclosed embodiments.

1. A printer apparatus comprising:
a print assembly comprising at least one conductive alignment sensor having a plurality of inductive coils configured to generate an electromagnetic field;
wherein the print assembly is configured to receive at least one substrate comprising at least one conductive portion printed thereon and align the at least one substrate such that the plurality of inductive coils and the at least one conductive portion substantially overlap with each other to form an electromagnetic field having a direction from the at least one conductive alignment sensor to the at least one conductive portion, wherein the direction of the electromagnetic field with respect to the at least one conductive alignment sensor forms an angle; and
wherein the at least one conductive alignment sensor is configured to detect a movement of the at least one conductive portion when a change to the angle causes a change in a current through the plurality of inductive coils.

2. The printer apparatus of claim 1, further comprising at least one control device communicatively coupled to the assembly, wherein the at least one control device is configured to receive information from the at least one conductive alignment sensor indicative of whether the at least one substrate is aligned or not aligned on the print assembly.

3. The print apparatus of claim 2, wherein the at least one control device is configured to communicate at least one stop signal to the pint assembly in response to receipt of information from the at least one conductive alignment sensor indicative that the at least one substrate is not aligned on the print assembly, and wherein the print assembly is configured to stop a printing process after receipt of the at least one stop signal from the at least one control device.

4. The print apparatus of claim 2, further comprising an alignment assembly communicatively coupled to the at least one control device, wherein the alignment assembly is configured to position the at least one substrate on the print assembly.

5. The print apparatus of claim 4, wherein the at least one control device is configured to communicate at least one realignment signal to the alignment assembly in response to receipt of information from the at least one conductive alignment sensor indicative that the at least one substrate is not aligned on the print assembly, and wherein the alignment assembly is configured to position the at least one conductive portion such that the change to the angle is negated after receipt of the at least one realignment signal from the at least one control device.

6.-7. (canceled)

8. The print apparatus of claim 1, wherein the at least one conductive portion extends in a substantially longitudinal direction along the at least one substrate, the at least one conductive portion being selected from a group consisting of a conductive line and a conductive dotted line with varying gaps between dots.

9. (canceled)

10. The print apparatus of claim 1, wherein the at least one substrate further comprises a conductive strain sensor configured to sense strain on the at least one substrate by measurement of an electrical field induced strain.

11. The print apparatus of claim 1, wherein the change in the current includes one or more of a directional change in the current and a flux density change.

12. (canceled)

13. The print apparatus of claim 1, wherein the at least one conductive alignment sensor includes an in-line Eddy current sensor array having an excitation coil and a detection coil each embedded in a magnetic core, wherein the excitation coil is positioned substantially perpendicular to the detection coil in such a manner that the at least one substrate passes between the excitation coil and the detection coil.

14.-16. (canceled)

17. The print apparatus of claim 1, wherein the print assembly further comprises at least one substrate holder having the at least one conductive alignment sensor dispersed thereon, the at least one substrate holder configured to hold at least a portion of the at least one substrate during a printing process.

18. The print apparatus of claim 1, wherein the print assembly further comprises at least one pattern roller configured to imprint the at least one conductive portion on the at least one substrate during a printing process.

19. The print apparatus of claim 1, wherein the at least one substrate comprises polyethylene terephthalate, polyethylene naphthalate, polyimide, glass, ceramic, metal, silicon, cellulose, or laminate.

20. (canceled)

21. The print apparatus of claim 1, wherein the printer apparatus is configured to print on the at least one substrate one or more electronic elements selected from a group consisting of an electronic wiring, a conductor, a resistor, a capacitor, a dielectric, an inductor, a diffractive optic element, a light guide, a diode, a transistor, a sensor, an indicator, a solar cell, an electronic circuit, a solar cell, a miniaturized fuel cell, a memory device, an optical waveguide, an optical microelectricromechanical systems array, a memory element, a radio-frequency identification element, a biocompatible electronic element, a battery, a display active matrix backplane, a nanoscale photovoltaic element and an optical read-only memory.

22.-31. (canceled)

32. A method to detect substrate alignment during a printing process, the method comprising:
providing a print assembly comprising at least one conductive alignment sensor having a plurality of inductive coils configured to generate an electromagnetic field;
providing at least one substrate comprising at least one conductive portion printed thereon;
aligning the at least one substrate on the print assembly by substantially overlapping the at least one conductive alignment sensor and the at least one conductive portion to form an electromagnetic field having a direction from the at least one conductive alignment sensor to the at least one conductive portion, wherein the direction of the electromagnetic field with respect to the at least one conductive alignment sensor forms an angle;
generating an electromagnetic field by applying a current across the plurality of inductive coils; and
printing at least one pattern on the at least one substrate.

33. The method of claim 32, further comprising determining that the at least one substrate is not aligned on the print assembly based upon a signal indicative of a change to the angle.

34.-35. (canceled)

36. The method of claim 32, wherein applying the current across the plurality of inductive coils comprises applying an alternating current at a frequency of about 800 kHz.

37. The method of claim 32, wherein applying the current across the plurality of inductive coils comprises applying a current of about 100 mA.

38. The method of claim 32, further comprising monitoring at least one characteristic associated with the electromagnetic field during the printing of the at least one pattern, wherein a change in the at least one characteristic is indicative of a misalignment between the at least one substrate and the print assembly.

39. The method of claim 38, wherein the at least one characteristic is selected from a group consisting of a voltage and a flux density.

40.-42. (canceled)

43. The method of claim 32, wherein the printing comprises printing the at least one conductive portion on the at least one substrate.

44.-81. (canceled)

82. A substrate for a printer apparatus configured to detect substrate alignment during a printing process, the substrate comprising:
at least one substrate material configured to receive a printed pattern thereon by the printer apparatus; and
at least one conductive portion printed on the at least one substrate material;
wherein the at least one substrate material is arranged in the printer apparatus by substantially overlapping the at least one conductive portion with a plurality of inductive coils of the printer apparatus to form an electromagnetic field having a direction from at least one conductive alignment sensor to the at least one conductive portion, wherein the direction of the electromagnetic field with respect to the at least one conductive alignment sensor forms an angle.

83. The substrate of claim 82, wherein the at least one conductive portion extends in a substantially longitudinal direction along the at least one substrate material, the at least one conductive portion being selected from a group consisting of a conductive line and a conductive dotted line having varying gaps between dots.

84. (canceled)

85. The substrate of claim 82, further comprising a conductive strain sensor arranged within the at least one substrate material, wherein the conductive strain sensor is configured to detect a strain on the at least one substrate material indicative of an electrical field induced strain.

86.-87. (canceled)
